(19) United States
(12) Patent Application Publication
(10) Pub. No.: US 2025/0021706 A1
(43) Pub. Date: Jan. 16, 2025

(54) MANUFACTURING MODEL CREATION DEVICE, MANUFACTURING MODEL CREATION METHOD, AND PROGRAM

(71) Applicant: MITSUBISHI HEAVY INDUSTRIES, LTD., Tokyo (JP)

(72) Inventors: Jun ETO, Tokyo (JP); Kengo YOSHIDA, Tokyo (JP); Toshiyuki TANAKA, Tokyo (JP); Shigeo HIDA, Tokyo (JP); Noritomo TAKATA, Tokyo (JP); Makoto KUREBAYASHI, Tokyo (JP)

(21) Appl. No.: 18/640,775

(22) Filed: Apr. 19, 2024

(30) Foreign Application Priority Data
Jul. 13, 2023 (JP) 2023-115238

(51) Int. Cl. G06F 30/12

(52) U.S. Cl. CPC G06F 30/12

(57) ABSTRACT

A manufacturing model creation device includes: a unit configured to create, on the basis of a design model as design information of a completed product to be manufactured by assembling a plurality of components, a plan model in which instruction information for manufacturing necessary for assembling the components is set for each of the components; and a unit configured to create a manufacturing model including a manufacturing instruction for a manufacturing target component by extracting component information of the manufacturing target component from the design model and adding, to the component information extracted, the instruction information of the manufacturing target component extracted from the plan model.

### CROSS-REFERENCE TO RELATED APPLICATIONS

This application claims the benefit of priority to Japanese Patent Application Number 2023-115238 filed on Jul. 13, 2023. The entire contents of the above-identified application are hereby incorporated by reference.

### TECHNICAL FIELD

The present disclosure relates to a manufacturing model creation device, manufacturing model creation method, and a program.

### RELATED ART

In manufacturing an aircraft, type certification based on a design model as design information of a completed product of the aircraft is conducted. In the type certification, the design or manufacturing process is subjected to a safety inspection or the like and, if the inspection is not passed, the design or the like will be changed. The design model is design information of a completed product of the aircraft, but for manufacturing, a drawing of and a processing instruction on each component constituting the aircraft is needed instead of a drawing of the completed product. For example, components constituting the aircraft such as a skin and a stringer are manufactured, a plurality of assembly processes are performed, and then the aircraft is completed. In each assembly process, holes are formed in the components, and the components are coupled with bolts, fasteners, or the like. The design model includes information for instructing the positions of the holes but does not include instruction information of which assembly process the holes are to be made and the components is to be coupled. In the assembly process, additional processing that is not related to the completed aircraft is often performed on the components. However, for the additional processing, a processing instruction different from the information included in the design model is required. In the case of the aircraft, the components are assembled while additional processing such as hole making and cutting of excess portions and tabs is performed on the components, and thus a packing style of an individual component (for example, a geometrical element such as holes, a tab, an excess portion, or the like) differs between at the time of completion and at the time of assembly, and a design drawing or the like (referred to as a manufacturing model) for manufacturing each component is separately required.

In the related art, planning of assembly processes is carried out on the basis of a design model, a requirement specification is set out if an individual instruction for manufacturing a component is necessary, and a manufacturing model of the component is created from the design model on the basis of the requirement specification in manufacturing the component. In the development of an aircraft, the design model is frequently changed and creating a manufacturing model takes a large amount of labor and time. A method of managing a design model by adding instruction information for manufacturing components and the like to the design model is conceivable. However, this method may have a large information amount of the design model, cause heavy processing using the design model, and disturb a designing work in a development phase.

JP 2015-79506 A discloses a system that outputs a graphical view for supporting processing operation and fastening operation for components constituting an aircraft. However, the technique disclosed of JP 2015-79506 A is not a technique for creating a graphical view from a design model.

### SUMMARY

Provided is a method for efficiently creating a manufacturing model including a manufacturing instruction for a component constituting a product from design information (a design model) indicating a state of the product at the time of completion.

The present disclosure provides a manufacturing model creation device, a manufacturing model creation method, and a program that can solve the above-described problems.

A manufacturing model creation device according to the present disclosure includes: a unit configured to create, on the basis of a design model as design information of a completed product to be manufactured by assembling a plurality of components, a plan model in which instruction information for manufacturing necessary for assembling the components is set for each component; and a unit configured to create a manufacturing model including a manufacturing instruction for a manufacturing target component by extracting component information of the manufacturing target component from the design model and adding, to the component information extracted, the instruction information of the manufacturing target component extracted from the plan model.

A manufacturing model creation method according to the present disclosure includes: a step of creating, on the basis of a design model as design information of a completed product to be manufactured by assembling a plurality of components, a plan model in which instruction information for manufacturing necessary for assembling the components is set for each component; and a step of creating a manufacturing model including a manufacturing instruction for a manufacturing target component by extracting component information of the manufacturing target component from the design model and adding, to the component information extracted, the instruction information of the manufacturing target component extracted from the plan model.

A program according to the present disclosure causes a computer to execute: a step of creating, on the basis of a design model as design information of a completed product to be manufactured by assembling a plurality of components, a plan model in which instruction information for manufacturing necessary for assembling the components is set for each component; and a step of creating a manufacturing model including a manufacturing instruction for a manufacturing target component by extracting component information of the manufacturing target component from the design model and adding, to the component information extracted, the instruction information of the manufacturing target component extracted from the plan model.

The manufacturing model creation device, the manufacturing model creation method, and the program of the present disclosure allows a manufacturing model including a manufacturing instruction for a component constituting a product to be efficiently created from a design model that is design information of the product at the time of completion.

### BRIEF DESCRIPTION OF DRAWINGS

The disclosure will be described with reference to the accompanying drawings, wherein like numbers reference like elements.

FIG. 1 is a block diagram illustrating an example of a manufacturing model creation device according to an embodiment.

FIG. 2 is a diagram illustrating the outlines of plan models and manufacturing models according to an embodiment.

FIG. 3 is a diagram illustrating a manufacturing model creation process according to an embodiment.

FIG. 4 is a diagram illustrating an example of a design model according to an embodiment.

FIG. 5A is a first diagram illustrating a relationship between a design model, a plan model, and a manufacturing model according to an embodiment.

FIG. 5B is a second diagram illustrating a relationship between a design model, a plan model, and a manufacturing model according to an embodiment.

FIG. 6 is a diagram illustrating an example of an assembly plan three-dimensional model according to an embodiment.

FIG. 7 is a diagram illustrating an example of a manufacturing three-dimensional model according to an embodiment.

FIG. 8 is a flowchart illustrating an example of an operation of the manufacturing model creation device according to an embodiment.

FIG. 9 is a diagram illustrating an example of a hardware configuration of the manufacturing model creation device according to an embodiment.

### DESCRIPTION OF EMBODIMENTS

### Embodiments

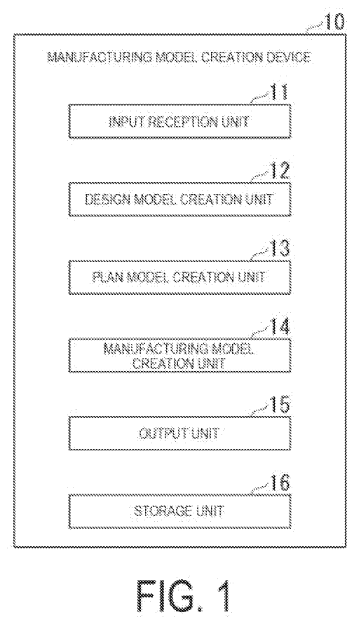

Hereinafter, a method for creating a manufacturing model according to the present disclosure will be described with reference to FIG. 1 to FIG. 9.

### Configuration

FIG. 1 is a block diagram illustrating an example of a manufacturing model creation device according to an embodiment.

A manufacturing model creation device 10 is configured by one or more computers. As illustrated in the drawing, the manufacturing model creation device 10 includes an input reception unit 11, a design model creation unit 12, a plan model creation unit 13, a manufacturing model creation unit 14, an output unit 15, and a storage unit 16.

The input reception unit 11 receives various information input by using an input device such as a keyboard, a mouse, a touch panel, or a button, instruction information for instructing start and end of processing, and the like. For example, the input reception unit 11 receives an assembly instruction such as positioning by a shim or sealing, hole making, riveting, or fastening, and manufacturing information such as surface treatment, coating, a tab, or an excess portion for each component of an aircraft, which are input to the manufacturing model creation device 10. A tab is a handle to be used to carry a component, and an excess portion is a region for adjustment which is manufactured to be slightly larger than a size designated by a design model. Tab and excess portions are eventually cut off.

The design model creation unit 12 creates a design model representing a packing style of an aircraft after the final assembly of the aircraft. The design model includes three-dimensional model information indicating the shape of the aircraft at the time of completion, coupling information such as fasteners and bolts as assembly information, positioning information by shims and sealants, and the like. The design model is divided in units of assembly processes and managed.

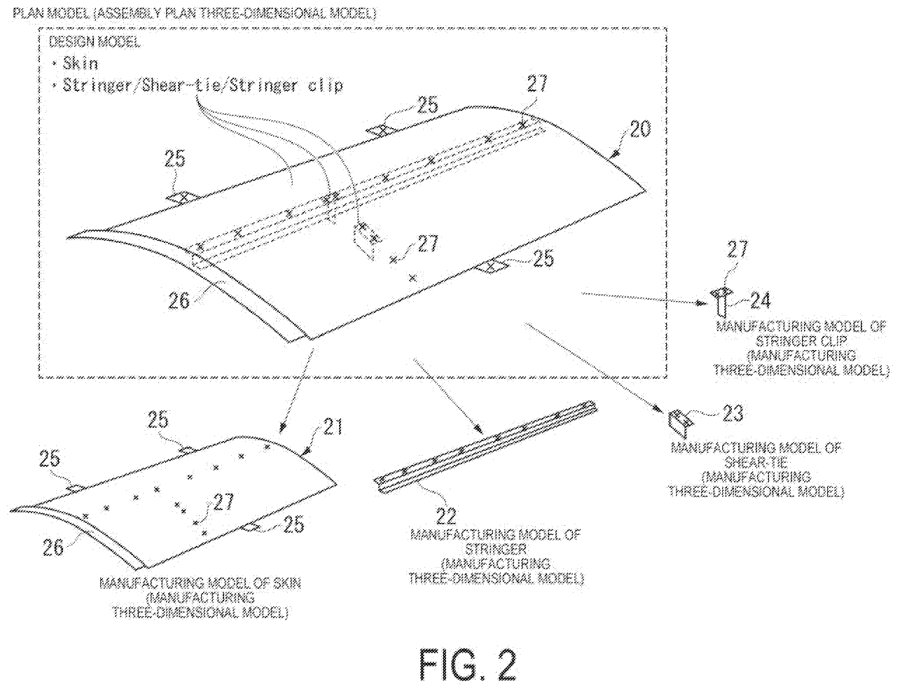

The plan model creation unit 13 creates a plan model related to the assembly of components and adds the plan model to the design model. The plan model is information in which a hole making instruction is organized for each component from the assembly information of the design model, and manufacturing information such as tabs, excess portions, and surface treatment and coating instructions is organized and created for each assembly process. The manufacturing information is not included in the design model because it is not necessary for a completed product and is information necessary for manufacturing or assembling components. In the design model, information such as a position and a vector of a hole (a direction in which the hole is to be made) may be designated. However, in order to actually make the hole, it is necessary to determine details after examining which assembly process is appropriate to make the hole, whether to make the hole in a state in which a component A and a component B are assembled, whether to make the hole in a single component, or the like, in consideration of the assembly procedure of components, and the like. That is, the product cannot be manufactured only by coupling information included in the assembly information of the design model. The plan model includes information in which a position and a vector of a hole to be made in each assembly process are organized for each component. The plan model is examined and organized by a person in charge of assembly per assembly process, that is, per assembly. An assembly is an aggregate of one or a plurality of components. For example, the fuselage of an aircraft is composed of a plurality of barrels, and one barrel is composed of a plurality of panels. For example, FIG. 2 illustrates an example in which one panel is regarded as one assembly. As illustrated in FIG. 2, a panel 20 includes a skin 21, a stringer 22, a shear tie 23, a stringer clip 24, and the like, and manufacturing information such as a hole making instruction for these components needs to be examined in a state in which these components are assembled into the panel 20. The person in charge of assembly examines, for example, the details of hole making and the necessity of additional processing of an excess portion per assembly. The person in charge of assembly inputs an examination result to the manufacturing model creation device 10 as a plan model. The plan model creation unit 13 creates data obtained by link-copying the design model and adds the input plan model to the created data. Data obtained by adding the plan model to the data obtained by link-copying the design model is referred to as an assembly plan three-dimensional model for a descriptive purpose. Link-copying is, for example, a function included in CAD software, and is a function by which when a name or a position of a certain element A (for example, a bolt) in the assembly information is changed in the design model, the changed content is automatically reflected in the element A in link-copy destination data. By using this function, when a change is made to the design model, the contents of the change can be automatically reflected in the assembly plan three-dimensional model. The link-copying function is not limited to a function included in the CAD software. For example, there may be a function implemented by which an identification number of an element A in link-copy destination data and an identification number of the element A in a copy source design model are managed in association with each other, and when a change is made to the element A in the design model, the change made to the design model is reflected in the element A having the corresponding identification number in the link-copy destination data. The plan model and the assembly three-dimensional model are created when the person in charge of assembly designs assembly processes and are utilized when the assembly processes are performed.

The manufacturing model creation unit 14 extracts information about a manufacturing target component from the design model and the plan model, copies the information without a link, and adds, to component information (a name, a size, and coordinate information of the component) extracted from the design model, manufacturing information such as a hole making instruction related to the component extracted from the plan model, thereby creating a manufacturing model. The manufacturing model creation unit 14 creates data obtained by copying the design model without a link and adds the plan model and the manufacturing model to the created data. Data obtained by adding the manufacturing model and the like to the data obtained by copying the design model without a link is referred to as a manufacturing three-dimensional model for a descriptive purpose. In the example of FIG. 2, for example, a manufacturing model and a manufacturing three-dimensional model of the skin 21, a manufacturing model and the like of the stringer 22, a manufacturing model and the like of the shear tie 23, and a manufacturing model and the like of the stringer clip 24 are created. Each of the manufacturing models and the like is delivered to a person in charge of manufacturing of each component and is used for manufacturing.

The design model creation unit 12, the plan model creation unit 13, and the manufacturing model creation unit 14 includes CAD software, for example. FIG. 2 illustrates the outlines of the design model, the plan model, and the manufacturing model. When the design model is displayed by the CAD software or the like, only a packing style in which the skin 21, the stringer 22, the shear tie 23, and the stringer clip 24 are assembled is displayed as a three-dimensional model. On the other hand, in the assembly plan three-dimensional model, the manufacturing information such as hole making instruction information necessary for assembling components (x marks in FIG. 2, only some of the x marks are denoted by the reference sign 27 for simplicity), a tab 25, and an excess portion 26 is displayed. In the manufacturing three-dimensional model, a packing style of each component and the manufacturing information derived from the plan model are displayed. The tab 25 and the excess portion 26 of the skin 21 are constituent elements required at the time of assembly, are finally cut off, and are not present in the completed product. Such a difference in the shape of a component between at assembly or manufacturing and in the completed product is referred to as a difference in a packing style. The manufacturing model creation method of the present embodiment allows for creating a manufacturing model including manufacturing or processing instructions for each assembly process, such as an instruction to create the tab 25 in an early assembly process and an instruction to cut the tab 25 in a later process and is effective for a product, such as an aircraft, having a packing style of a component different between at assembly or manufacturing and in the completed product.

The output unit 15 outputs the design model, the plan model, and the manufacturing model to a display device, an electronic file, or the like.

The storage unit 16 stores the design model, the plan model, the manufacturing model, and the like.

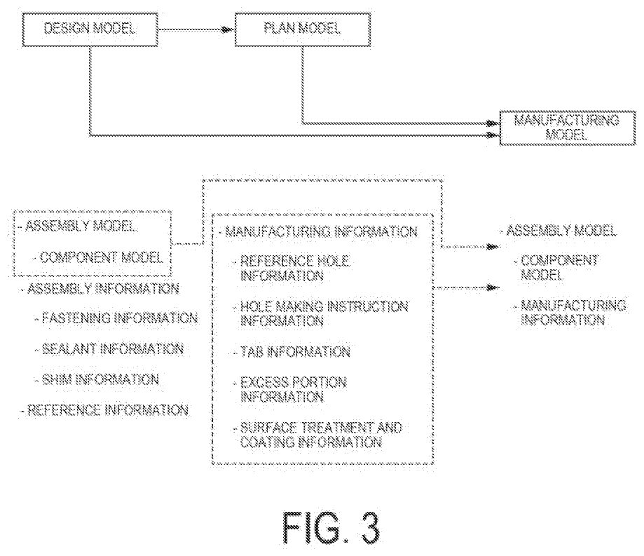

FIG. 3 illustrates an outline of a manufacturing model creation process. First, a design model is created. In the design model, component models (types, sizes, and the like of components) of the respective components, an assembly model (what components constitute an assembly), assembly information (fastening information, sealant information, and shim information of the components), a reference standard (for example, a reference plane in a three-dimensional space on which the panel 20 illustrated in FIG. 2 is arranged, and one barrel is formed by arranging the panel along the reference plane), and the like are organized for each assembly process (per assembly). The design model is used for type certification or the like. After the design model is created, a plan model is created without waiting for the completion of type certification or the like.

The plan model includes manufacturing information such as reference hole information, hole making instruction information (hole position, hole size, hole making direction, and the like), tab information (at which position and in what shape a tab is to be made), excess portion information (at which position and in what shape an excess portion is to be made), and surface treatment and coating information (surface treatment method and what kind of coating is to be performed). The plan model is created for each assembly process by a person in charge of assembly who has knowledge by examining in what procedure assembly is to be performed and in which assembly process processing is required in order to achieve the package style and the assembly information indicated by the design model. More specifically, a hole making instruction is organized for each target component by link-copying necessary elements (a point of a hole position and a vector indicating a direction in which a hole is to be made) from the assembly information of the design model. A hole diameter, penetration, and the like are set for the target component with reference to a geometrical set name and a parameter of the assembly information. Instructions for a tab, an excess portion, and surface treatment and coating are created by referring to necessary elements (a surface, a contour, and the like) from the design model. For example, an appropriate value is set to each parameter of a parametric model, whereby a shape (packing style) is designated for each component. At the time of design change, the elements of the plan model are automatically updated by link-copying. After the plan model is created, a manufacturing model is created from the design model and the plan model.

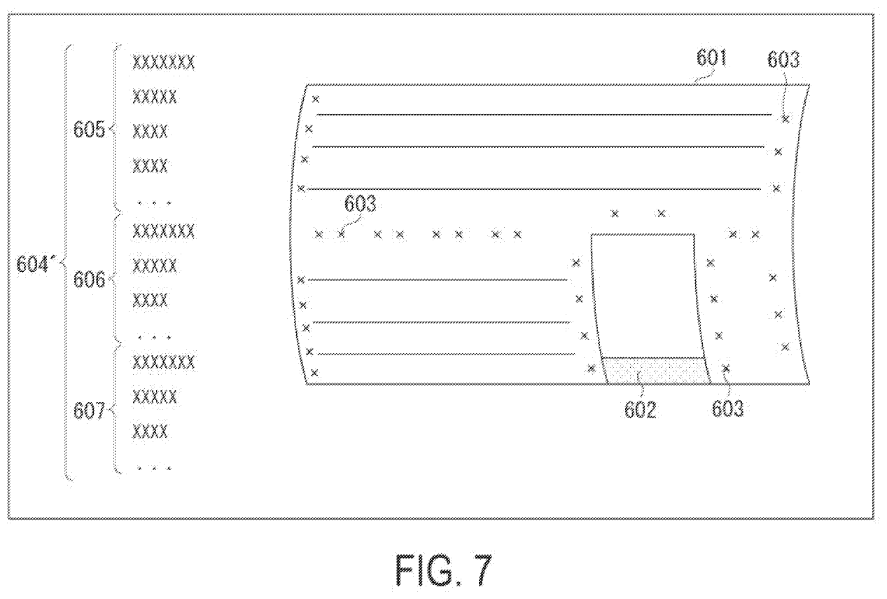

The manufacturing model is generated for each component and includes an assembly model (which assembly the component constitutes), a component model (a type and a size of the component), and manufacturing information (additional processing to be performed on the component). All of these pieces of information are extracted from the design model or the plan model by referring to names (for example, names of components such as a skin and a stringer), numbers, and the like. The manufacturing model is displayed in a form in which a target element of the plan model is added to the tree of the assembly information of the design model of a target component (FIG. 7). Each time a design change is made to the design model, a manufacturing model is generated from a new design model and a new plan model.

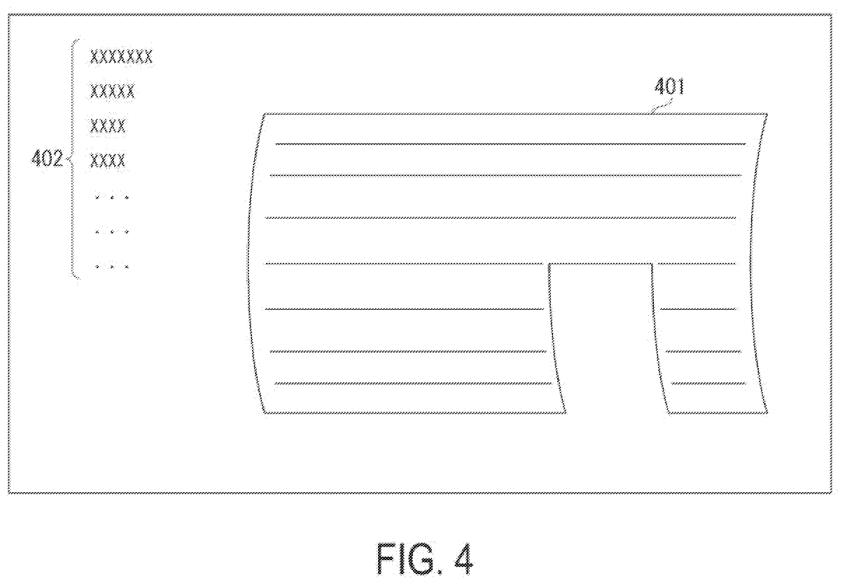

FIG. 4 illustrates an example of a design model. FIG. 4 illustrates an example of a schematic display when a design model of a panel of a fuselage portion of an aircraft is displayed using a function of the CAD software. As illustrated in the drawing, only a three-dimensional model 401 of the panel at the time of completion and tree information 402 are displayed. Assembly information is displayed in the tree information 402.

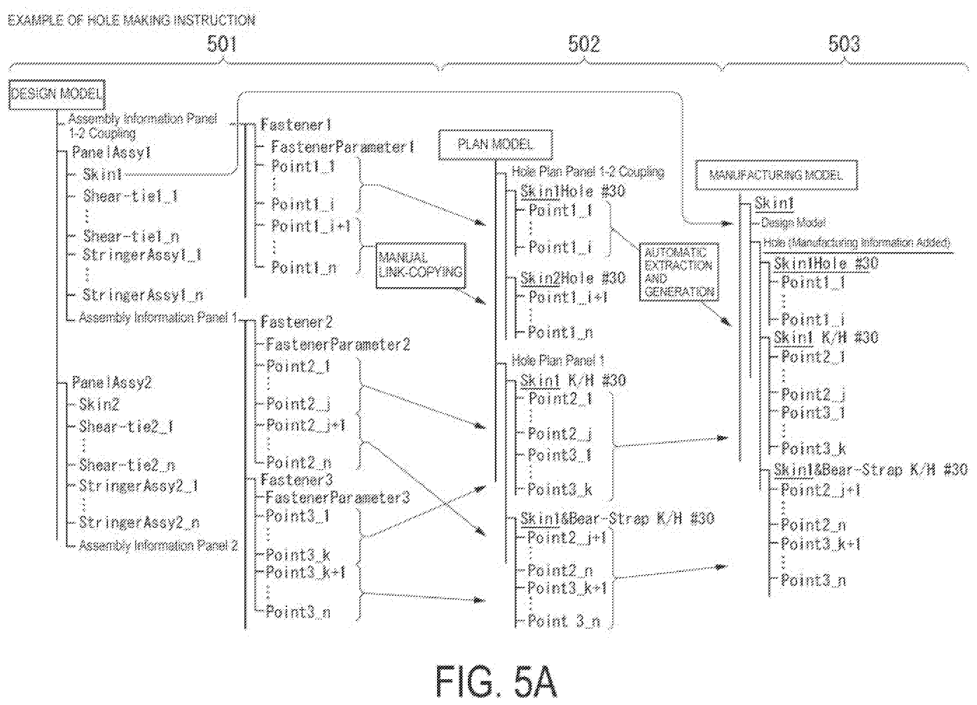

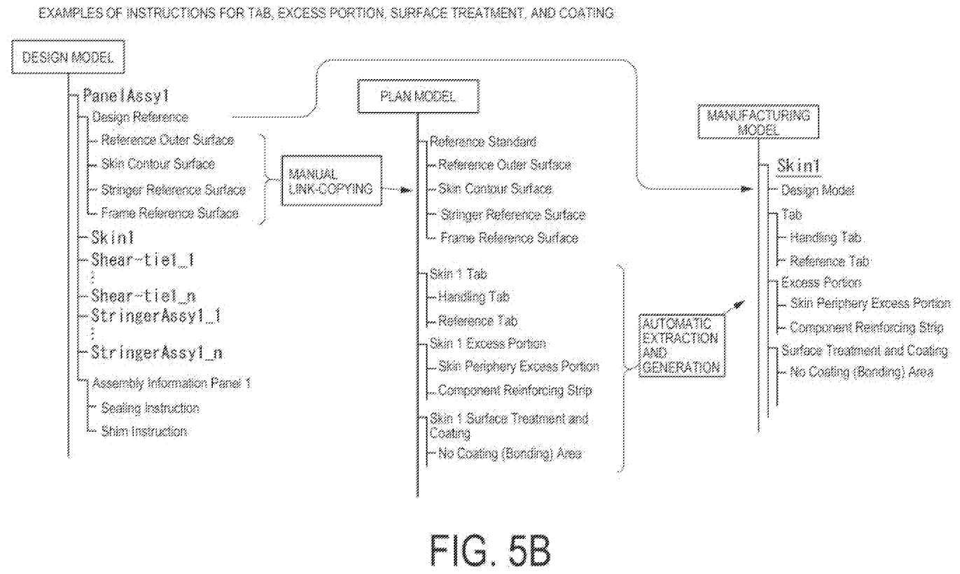

An example of a design model is illustrated at 501 of FIG. 5A. An assembly model of a panel and assembly information relating to hole making are illustrated in 501 of FIG. 5A. In the tree information 402 of FIG. 4, for example, information as illustrated in 501 of FIG. 5A is displayed. As illustrated in the drawing, the panel includes Panel Assy 1 and Panel Assy 2. Panel Assy 1 includes Skin 1, Shear-ties 1_1 to 1_n, Stringer Assys 1_1 to 1_n, and the like. Similarly, Panel Assy 2 includes Skin 2, Shear-ties 2_1 to 2_n, Stringer Assys 2_1 to 2_n, and the like. Fastener 1 is defined as assembly information for coupling Panel Assy 1 and Panel Assy 2, and hole position information Point 1_1 or the like for Fastener 1 is defined. Fasteners 2 and 3, hole position information Points 2_1 and 3_1, and the like are defined as the assembly information of Panel 1.

An example of a plan model is illustrated at 502 of FIG. 5A. The plan model is created by manually link-copying the assembly information of the design model. In the example of FIG. 5A, for example, Points 1_1 to 1_i of the design model are organized as a hole “Skin 1 Hole #30” to be made in Skin 1. Points 2_1 to 2_j and Points 3_1 to 3_k of the design model are organized as a hole “Skin 1 K/H #30” to be made in Skin 1. K/H refers to an important hole used for positioning. In the example of FIG. 5A, only the position information of the holes is described as a hole making instruction, but actually, vector information indicating directions in which the holes are made is included.

An example of a manufacturing model is illustrated at 503 of FIG. 5A.

In the manufacturing model, component information including the name of a target component is extracted from the design model and the plan model on the basis of the name of the target component. For example, when Skin 1 is designated as a target component, the component model Skin 1 is extracted from the design model, and the hole making instruction information whose name includes “Skin 1” (for example, “Skin 1 Hole #30” described above) is extracted from the plan model.

FIG. 5B illustrates examples of instructions for a tab, an excess portion, surface treatment, and coating. The design model includes various design references (a reference outer surface, a skin contour surface, a stringer reference surface, and a frame reference surface), Skin 1, Shear-ties 1_1 to 1_n, Stringer Assys 1_1 to 1_n, and assembly information for Panel Assy 1. When manufacturing information such as a tab and an excess portion is set in the plan model, the design model is link-copied, and for Skin 1, for example, an item called Skin 1 Tab is provided, and the position and the shape of the tab are set. A reference standard can be used to set the shape of the tab or the like. Similarly, an item “Skin 1 Excess Portion” is provided to set the position, the shape, and the like of the excess portion, and an item “Skin 1 Surface Treatment/Coating” is provided to set an instruction for surface treatment or coating. The manufacturing model of Skin 1 is created by extracting component information such as a component name from the design model and extracting manufacturing information such as a tab, an excess portion, surface treatment, and coating from the plan model. An example of a hole making instruction has been described in FIG. 5A and an example of a tab and an excess portion has been described in FIG. 5B. However, these are not actually separated from each other, and, for example, the manufacturing model of Skin 1 includes both the hole making instruction illustrated in FIG. 5A and the manufacturing information illustrated in FIG. 5B.

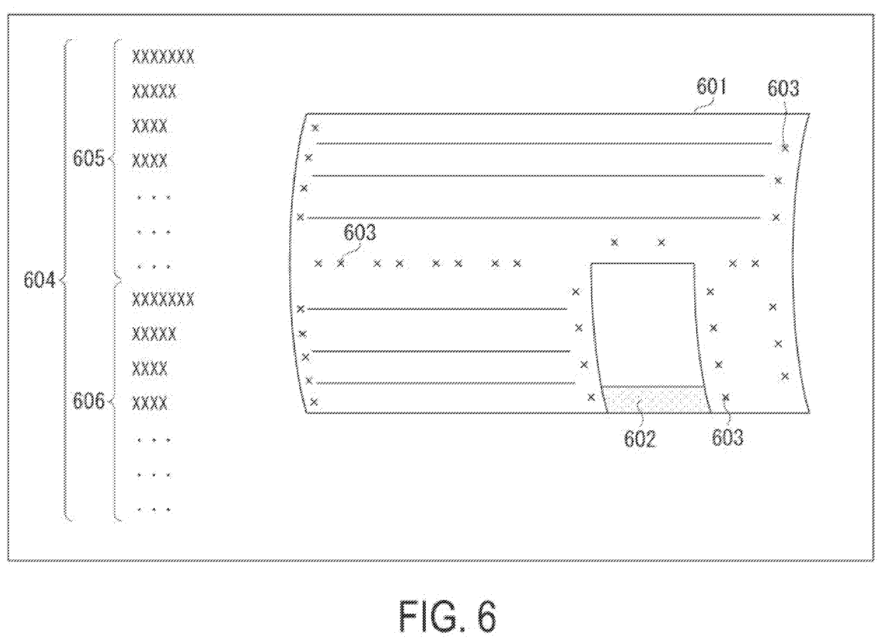

FIG. 6 illustrates an example of an assembly plan three-dimensional model. FIG. 6 is a schematic display example when data in which a plan model is added to the design model of FIG. 4 is displayed by using a function of the CAD software. As illustrated in the drawing, an excess portion 602 and hole making instruction information 603 (x marks, only part which are denoted by a reference sign 603), and the like are added to a three-dimensional model 601 of a panel. In tree information 604 in which assembly information and the like are displayed, a plan model 606 (for example, 502 in FIG. 5A) is added in addition to assembly information 605 (for example, 501 in FIG. 5A) of the design model. The plan model 606 includes various design references such as hole making instruction information, information such as the shape of the excess portion 602, information such as the shape of a tab when there is a tab, instruction information for coating or surface treatment, reference outer surface information, and skin contour surface information.

FIG. 7 illustrates an example of a manufacturing three-dimensional model. FIG. 7 is a schematic display example when a manufacturing model created from the design model of FIG. 4 and the plan model of FIG. 6 is displayed using a function of the CAD software. As illustrated in the drawing, in tree information 604′, a manufacturing model 607 (for example, 503 in FIG. 5A) of a target component is added in addition to the assembly information 605 (for example, 501 in FIG. 5A) of the design model and the plan model 606 (for example, 502 in FIG. 5A). The manufacturing model 607 includes hole making instruction information, shape information of an excess portion, shape information of a tab, coating instruction information, surface treatment instruction information, reference outer surface information, skin contour surface information, stringer reference surface information, frame reference surface information, and the like related to the target component.

### Operation

An operation of the manufacturing model creation device 10 of the present embodiment will be described.

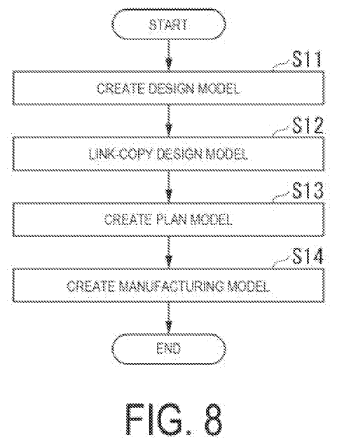

FIG. 8 is a flowchart illustrating an example of the operation of the manufacturing model creation device according to an embodiment.

First, a designer creates a design model using the design model creation unit 12 (CAD software) (step S11). The design model creation unit 12 stores the created design model in the storage unit 16. The design model is divided for each assembly process. Next, a person in charge of assembly link-copies the design model in the storage unit 16 (step S12). When the person in charge of assembly performs a predetermined operation, the output unit 15 outputs the link-copied design model to a display device or the like. The person in charge of assembly refers to the link-copied design model to design an assembly procedure and processing such as hole making, coating, and tab making required in each assembly process. The person in charge of assembly sorts manufacturing information such as hole making, coating, and tab making for each assembly process and for each component to be assembled in each assembly process, thereby creating plan models (step S13). As illustrated in FIG. 5A and FIG. 5B, the plan models are organized for each component and for each piece of manufacturing information, and are given names including, for example, component name and a manufacturing name (Hole, K/H, Tab, Excess Portion, or the like). For example, in the case of a plan model that instructs to make a hole in Skin 1, a name such as “Skin 1 Hole #30” is given as in the example of FIG. 5A. Then, specific manufacturing information such as a hole making position and a tab shape is set under the name. The person in charge of assembly inputs the created plan models to the manufacturing model creation device 10. The input reception unit 11 acquires the input plan models and outputs the plan models to the plan model creation unit 13. The plan model creation unit 13 stores the plan models in the storage unit 16. The plan model creation unit 13 adds the plan models to the link-copied design model to create an assembly plan three-dimensional model. The output unit 15 outputs the assembly plan three-dimensional model to a display device or the like. When the plan models are added, the plan models are added to the tree information 604 and the contents of the plan models (the excess portion 602, the hole making instruction information 603, and the like in FIG. 6) are reflected in the three-dimensional model 601 as illustrated in FIG. 6. Next, a person in charge instructs creation of a manufacturing model. In the case of manufacturing the skin 21, the person in charge inputs, for example, Skin 1 as a manufacturing target component to the manufacturing model creation device 10. The input reception unit 11 acquires the input component name and outputs the component name to the manufacturing model creation unit 14. The manufacturing model creation unit 14 refers to the design model in the storage unit 16 and extracts a component model to which the same name as the designated component name is set. The manufacturing model creation unit 14 refers to the plan models in the storage unit 16 and extracts plan models whose names include the designated component name. The manufacturing model creation unit 14 creates a manufacturing model by combining the information extracted from the design model and the information extracted from the plan model (step S14). For example, the manufacturing model creation unit 14 may create data having a tree structure in which a name of a manufacturing target component is set as a root, a name of each plan model is set to each node, and specific manufacturing information is set to leaves under each node. The manufacturing model creation unit 14 non-link-copies the design model and adds the plan models and the manufacturing model to the non-link-copied design model to create a manufacturing three-dimensional model. The output unit 15 outputs the manufacturing three-dimensional model to a display device or the like (FIG. 7). A person in charge of manufacturing can manufacture a component for which he/she is responsible by referring to the manufacturing three-dimensional model. A supplier outside the company may be requested to manufacture the component. In that case, a file is created by extracting only information necessary for manufacturing the component from the created manufacturing three-dimensional model, and the created file is provided to the supplier. This makes it possible to request the manufacturing of the component without providing unnecessary information.

### Effects

As described above, the manufacturing model creation method of the present embodiment allows a manufacturing model including a design drawing and a processing instruction for a component constituting a product to be efficiently created from a design model that is design information of the product at the time of completion. Adding technical instruction information to be referred to in manufacturing and assembling components to a three-dimensional CAD model (design model) allows the technical instruction information for assembling and manufacturing the components to be centrally managed (for example, FIG. 6 and FIG. 7). This allows for reducing a redundant work such as creating a new drawing or the like for manufacturing from a design model in a manufacturing preparation stage and to preventing a mismatch with the design model or the like. Examining an assembly plan before creating a manufacturing model and creating the assembly plan as a plan model allows for efficient creation of the assembly plan and a manufacturing instruction for a component without errors. Regarding a method of adding manufacturing information to a design model, the present embodiment allows for, by separating design information from manufacturing information, creation of the assembly plan and creation of a manufacturing model to which the manufacturing information is added without interfering with a design work in a development phase. In creating a plan model, the plan model is created by using data link-copied from a design model, and thus even when a change is made to the design model, the change can be promptly reflected in link destination data and the plan model can be changed or corrected as necessary. Regarding a manufacturing model, since data of a manufacturing target component is extracted from the design model and the plan model by copying without a link each time, even when a design change is made, a situation in which a change of the design model is automatically reflected in the manufacturing model to cause confusion in a manufacturing section can be prevented by operation to create the manufacturing model after confirming the changed design model or the changed plan model.

In the related art, an assembly plan is developed after a design model is released, and manufacturing information is organized and transmitted to a person in charge of manufacturing in the form of data in another format such as paper. On the other hand, the present embodiment can advance a work and create and confirm a plan model in advance using preceding data of a design model at a layout stage in advance. This can improve a drawing quality before the issuance of a drawing of a design model. Further, updating the plan model after the issuance of a drawing of the design model and automatically generating a manufacturing model allows effects such as unification of data (centralization of the design model, the plan models, and the manufacturing models), reduction of man-hours, and prevention of drawing errors to be obtained. Since the plan model can be automatically updated by link-copying of the design model, a change from the design model at the layout stage can be promptly reflected in the plan model and shorten a manufacturing lead time after a formal manufacturing model is released.

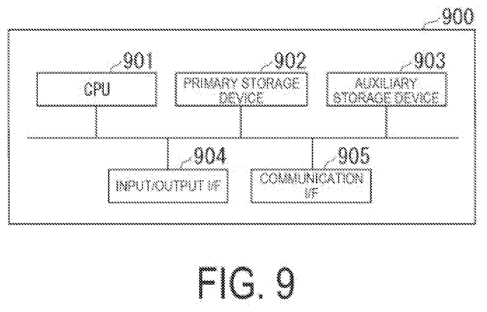

FIG. 9 is a diagram illustrating an example of a hardware configuration of the manufacturing model creation device 10 according to an embodiment.

A computer 900 includes a CPU 901, a primary storage device 902, an auxiliary storage device 903, an input/output interface 904, and a communication interface 905.

The manufacturing model creation device 10 described above is implemented in the computer 900. The functions described above are stored in the auxiliary storage device 903 in a format of a program. The CPU 901 reads the program from the auxiliary storage device 903, loads the program into the primary storage device 902, and executes the above-mentioned processing in accordance with the program. The CPU 901 secures a storage area in the primary storage device 902 in accordance with the program. The CPU 901 secures a storage area for storing data under processing in the auxiliary storage device 903 in accordance with the program.

A program for implementing the whole or part of functions of the manufacturing model creation device 10 may be recorded in a computer readable recording medium, and a computer system may be caused to read and execute the program recorded in the recording medium to execute the processing of respective functional units. The “computer system” here includes hardware such as an operating system (OS) or peripheral equipment. If a WWW system is used, the “computer system” also includes a home page providing environment (or a display environment). The “computer readable recording medium” refers to a portable medium such as a CD, a DVD, or a USB device, or a storage device such as a hard disk built in the computer system. When this program is distributed to the computer 900 through a communication line, the computer 900 having received the distribution may load the program into the primary storage device 902 and may execute the above-mentioned processing. The above-described program may implement part of the functions described above, and furthermore, also implement the functions described above in combination with a program already recorded in the computer system.

In the foregoing, some embodiments of the present disclosure have been described, but all of these embodiments are merely illustrative and are not intended to limit the scope of the invention. These embodiments may be implemented in various other forms, and various omissions, substitutions, and alterations may be made without departing from the gist of the invention. These embodiments and modifications are included in the scope and gist of the invention and are also included in the scope of the invention described in the claims and equivalents thereof.

### Supplementary Notes

The manufacturing model creation device, the manufacturing model creation method, and the program described in the embodiment can be understood as follows, for example.
(1) A manufacturing model creation device according to a first aspect includes: a unit configured to create, on the basis of a design model as design information of a completed product to be manufactured by assembling a plurality of components, a plan model in which instruction information for manufacturing necessary for assembling the components is set for each of the components; and a unit configured to create a manufacturing model including a manufacturing instruction for a manufacturing target component by extracting component information of the manufacturing target component from the design model and adding, to the component information extracted, the instruction information of the manufacturing target component extracted from the plan model.

This allows the manufacturing model including a design drawing and a processing instruction for a component constituting a product to be efficiently created from the design model that is design information of the product at the time of completion.
(2) A manufacturing model creation device according to a second aspect is the manufacturing model creation device according to (1). The unit configured to create a plan model creates an assembly plan three-dimensional model in which the plan model is added to a three-dimensional CAD model of the completed product and displays the assembly plan three-dimensional model.

This allows the assembly plan three-dimensional model to which the plan model is added to be referred to without modifying the three-dimensional CAD model of the design model. This allows design information and instruction information for assembly to be centrally managed.
(3) A manufacturing model creation device according to a third aspect is the manufacturing model creation device according to (1) or (2). The unit configured to create a manufacturing model creates a manufacturing three-dimensional model in which the manufacturing model is added to a three-dimensional CAD model of the completed product and displays the manufacturing three-dimensional model.

This allows the manufacturing three-dimensional model to which the manufacturing model is added to be referred to without modifying the three-dimensional CAD model of the design model. This allows design information and instruction information for manufacturing to be centrally managed.
(4) A manufacturing model creation device according to a fourth aspect is the manufacturing model creation device according to any one of (1) to (3). The plan model is created for an individual assembly process of the product.

The manufacturing information of the components needs to be considered with the components assembled. Thus, creating a plan model for the individual assembly process of the product, per assembly allows manufacturing information without errors to be added.
(5) A manufacturing model creation device according to a fifth aspect is the manufacturing model creation device according to any one of (1) to (4). The instruction information includes information for instructing processing of a hole making, an excess. portion, and a handle to be used for carrying the components.

This can manufacture a hole making, an excess portion, and a tab necessary for assembling the components.
(6) A manufacturing model creation device according to a sixth aspect is the manufacturing model creation device according to any one of (1) to (5). The unit configured to create a plan model copies, when a change is made to the design model, the design model in a mode in which the change is also reflected in copy destination data of the design model and creates the plan model on the basis of the design model copied.

This allows, in the case of a design change (a change in the design model), the change to be promptly reflected in the design model of the link-copy destination on the plan model side. Promptly changing the plan model or the like in response to the design change allows the state of the plan model corresponding to the latest design model to be managed. The design model is automatically updated, thus allowing the time and effort for reflecting the change into the link-copy destination to be eliminated.
(7) A manufacturing model creation method according to a seventh aspect includes: a step of creating, on the basis of a design model as design information of a completed product to be manufactured by assembling a plurality of components, a plan model in which instruction information for manufacturing necessary for assembling the components is set for each of the components; and a step of creating a manufacturing model including a manufacturing instruction for a manufacturing target component by extracting component information of the manufacturing target component from the design model and adding, to the component information extracted, the instruction information of the manufacturing target component extracted from the plan model.
(8) A program according to an eighth aspect causes a computer to execute: a step of creating, on the basis of a design model as design information of a completed product to be manufactured by assembling a plurality of components, a plan model in which instruction information for manufacturing necessary for assembling the components is set for each of the components; and a step of creating a manufacturing model including a manufacturing instruction for a manufacturing target component by extracting component information of the manufacturing target component from the design model and adding, to the component information extracted, the instruction information of the manufacturing target component extracted from the plan model.

While preferred embodiments of the invention have been described as above, it is to be understood that variations and modifications will be apparent to those skilled in the art without departing from the scope and spirit of the invention. The scope of the invention, therefore, is to be determined solely by the following claims.

1. A manufacturing model creation device, comprising:
a unit configured to create, on the basis of a design model as design information of a completed product to be manufactured by assembling a plurality of components, a plan model in which instruction information for manufacturing necessary for assembling the components is set for each of the components; and
a unit configured to create a manufacturing model including a manufacturing instruction for a manufacturing target component by extracting component information of the manufacturing target component from the design model and adding, to the component information extracted, the instruction information of the manufacturing target component extracted from the plan model.

2. The manufacturing model creation device according to claim 1, wherein the unit configured to create a plan model creates an assembly plan three-dimensional model in which the plan model is added to a three-dimensional CAD model of the completed product and displays the assembly plan three-dimensional model.

3. The manufacturing model creation device according to claim 1, wherein the unit configured to create a manufacturing model creates a manufacturing three-dimensional model in which the manufacturing model is added to a three-dimensional CAD model of the completed product and displays the manufacturing three-dimensional model.

4. The manufacturing model creation device according to claim 1, wherein the plan model is created for an individual assembly process of the product.

5. The manufacturing model creation device according to claim 1, wherein the instruction information includes information for instructing processing of a hole making, an excess portion, and a handle to be used for carrying the components.

6. The manufacturing model creation device according to claim 1, wherein the unit configured to create a plan model copies, when a change is made to the design model, the design model in a mode in which the change is also reflected in copy destination data of the design model and creates the plan model on the basis of the design model copied.

7. A manufacturing model creation method, comprising:
a step of creating, on the basis of a design model as design information of a completed product to be manufactured by assembling a plurality of components, a plan model in which instruction information for manufacturing necessary for assembling the components is set for each of the components; and a step of creating a manufacturing model including a manufacturing instruction for a manufacturing target component by extracting component information of the manufacturing target component from the design model and adding, to the component information extracted, the instruction information of the manufacturing target component extracted from the plan model.

8. A non-transitory computer readable storage medium storing a program causing a computer to execute:
a step of creating, on the basis of a design model as design information of a completed product to be manufactured by assembling a plurality of components, a plan model in which instruction information for manufacturing necessary for assembling the components is set for each of the components; and a step of creating a manufacturing model including a manufacturing instruction for a manufacturing target component by extracting component information of a manufacturing target component from the design model and adding, to the component information extracted, the instruction information of the manufacturing target component extracted from the plan model.
